(19) United States
(12) Patent Application Publication
(10) Pub. No.: US 2022/0131057 A1
(43) Pub. Date: Apr. 28, 2022

(54) MICRO LIGHT-EMITTING DIODE

(71) Applicant: PlayNitride Display Co., Ltd., MiaoLi County (TW)

(72) Inventors: Yu-Yun Lo, MiaoLi County (TW); Yi-Chun Shih, MiaoLi County (TW); Bo-Wei Wu, MiaoLi County (TW); Chang-Feng Tsai, MiaoLi County (TW)

(73) Assignee: PlayNitride Display Co., Ltd., MiaoLi County (TW)

(21) Appl. No.: 17/117,143

(22) Filed: Dec. 10, 2020

(30) Foreign Application Priority Data
Oct. 27, 2020 (TW) 109137208

(51) Int. Cl. H01L 33/62; H01L 33/22; H01L 33/38; H01L 27/15

(52) U.S. Cl. CPC H01L 33/62; H01L 27/156; H01L 33/382; H01L 33/22

(57) ABSTRACT

A micro light-emitting diode disposed on and electrically connected to a circuit substrate includes: an epitaxial structure, at least one first electrode, a second electrode, and an insulating layer. The epitaxial structure includes a first semiconductor layer, a light emitting layer and a second semiconductor layer stacked sequentially. The first electrode is electrically connected to the first semiconductor layer and extends from a side of the first semiconductor layer along at least one side surface of the epitaxial structure to a position between the second semiconductor layer and the circuit substrate. The second electrode is located below the second semiconductor layer and is electrically connected to the second semiconductor layer. The insulating layer is disposed at least between the at least one first electrode and the light emitting layer of the epitaxial structure and between the at least one first electrode and the second semiconductor layer of the epitaxial layer.

### CROSS-REFERENCE TO RELATED APPLICATION

This application claims the priority benefit of Taiwan application serial no. 109137208, filed on Oct. 27, 2020. The entirety of the above-mentioned patent application is hereby incorporated by reference herein and made a part of this specification.

### BACKGROUND

### Technical Field

The disclosure relates to a micro light-emitting diode, and in particular to a micro light-emitting diode with a higher bonding yield.

### Description of Related Art

Vertical light-emitting diodes and flip-chip light-emitting diodes are two common forms of existing light-emitting diodes. The two electrodes of a vertical light-emitting diode are located on two opposite sides of the vertical light-emitting diode. Since one of the electrodes is required to be bonded to the circuit board through wire bonding, the bonding yield is limited. On the other hand, a flip-chip light-emitting diode requires a conductive hole or a mesa formed on the semiconductor layers so that one of the semiconductor layers is electrically connected to the electrode. When the light-emitting diode is scaled down to a micron-level micro light-emitting diode and applied to a display device, it is difficult to reduce the overall size.

### SUMMARY

The disclosure provides a micro light-emitting diode which exhibits characteristics of a vertical light-emitting diode and a flip-chip light-emitting diode.

A micro light-emitting diode according to an aspect of the disclosure is adapted for being disposed on and electrically connected to a circuit substrate. The micro light-emitting diode includes an epitaxial structure, at least one first electrode, a second electrode, and an insulating layer. The epitaxial structure includes a first semiconductor layer, a light emitting layer, and a second semiconductor layer stacked in sequence. At least one first electrode is electrically connected to the first semiconductor layer and extends from a side of the first semiconductor layer along at least one side surface of the epitaxial structure to between the second semiconductor layer and the circuit substrate. The second electrode is located below the second semiconductor layer and is electrically connected to the second semiconductor layer. The insulating layer is disposed at least between the at least one first electrode and the light emitting layer of the epitaxial structure and between the at least one first electrode and the second semiconductor layer.

In an embodiment of the disclosure, the micro light-emitting diode further includes a conductive layer, which is disposed on the first semiconductor layer and contacts the first semiconductor layer, and the at least one first electrode contacts and is electrically connected to the conductive layer.

In an embodiment of the disclosure, a projection area of the conductive layer on the circuit substrate entirely covers projection areas of the epitaxial structure, the at least one first electrode, and the insulating layer on the circuit substrate.

In an embodiment of the disclosure, a projection area of the conductive layer on the circuit substrate is smaller than a projection area of the epitaxial structure, the at least one first electrode, and the insulating layer on the circuit substrate.

In an embodiment of the disclosure, a projection area of the conductive layer on the epitaxial structure covers 80% or more of an area of the epitaxial structure.

In an embodiment of the disclosure, a ratio of a projection area of the conductive layer on the circuit substrate to a projection area of the epitaxial structure to the circuit substrate is between 80% and 110%.

In an embodiment of the disclosure, a thickness of the conductive layer is smaller than a thickness of each of the at least one first electrode.

In an embodiment of the disclosure, the micro light-emitting diode further includes a first light guide layer, disposed on the conductive layer, and the conductive layer is located between the first light guide layer and the first semiconductor layer. A refractive index of the conductive layer is greater than a refractive index of the first light guide layer.

In an embodiment of the disclosure, the micro light-emitting diode further includes a second light guide layer, disposed on the first light guide layer, and the first conductive layer is located between the second light guide layer and the conductive layer. A refractive index of the first light guide layer is greater than a refractive index of the second light guide layer.

In an embodiment of the disclosure, a projection area of each of the at least one first electrode on the circuit substrate is greater than or equal to a projection area of the second electrode on the circuit substrate.

In an embodiment of the disclosure, a projection area of the at least one first electrode on the epitaxial structure is equal to a projection area of the second electrode on the epitaxial structure.

In an embodiment of the disclosure, the at least one first electrode includes a plurality of first electrodes, the at least one side surface includes a plurality of side surfaces, and the first electrodes extend along the side surfaces of the epitaxial structure to below the second semiconductor layer.

In an embodiment of the disclosure, a projection area of the at least one first electrode on the circuit substrate does not overlap with a projection area of the epitaxial structure on the circuit substrate.

In an embodiment of the disclosure, the at least one first electrode directly contacts the first semiconductor layer.

In an embodiment of the disclosure, the at least one first electrode extends onto the first semiconductor layer.

A display device of the disclosure includes a display panel and a plurality of micro light-emitting diodes stacked below the display panel.

In summary, the first electrode of the micro light-emitting diode according to the embodiments of the disclosure extends from a side of the first semiconductor layer along the at least one side surface of the epitaxial structure to between the second semiconductor layer and the circuit substrate, and the second electrode is located below the second semiconductor layer. Therefore, different from a vertical light-emitting diode, the first electrode and the second electrode of the micro light-emitting diode according to the embodiments of the disclosure are located on the same side of the epitaxial structure. The first electrode and the second electrode can be directly bonded to the circuit substrate without wire bonding. Thus, the bonding yield can be high. In addition, different from a flip-chip light-emitting diode, the micro light-emitting diode according to the embodiments of the disclosure has the design of the first electrode extending from a side of the first semiconductor layer along the at least one side surface of the epitaxial structure to below the second semiconductor layer. In this way, it is not required to manufacture a conductive hole or a mesa on the epitaxial structure, and the size of the micro light-emitting diode is thus reduced. That is, the micro light-emitting diode according to the embodiments of the disclosure exhibits the characteristics of the vertical light-emitting diode and the flip-chip light-emitting diode.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a schematic cross-sectional view of a display device according to an embodiment of the disclosure.

FIG. 1B is a schematic cross-sectional view of a micro light-emitting diode according to an embodiment of the disclosure.

FIG. 1C is a schematic top view of FIG. 1B.

FIG. 2 is a schematic cross-sectional view of a micro light-emitting diode according to another embodiment of the disclosure.

FIG. 3A is a schematic cross-sectional view of a micro light-emitting diode according to another embodiment of the disclosure.

FIG. 3B is a schematic top view of FIG. 3A.

FIG. 3C is a schematic top view of a micro light-emitting diode according to another embodiment of the disclosure.

FIG. 4A is a schematic cross-sectional view of a micro light-emitting diode according to another embodiment of the disclosure.

FIG. 4B is a schematic top view of FIG. 4A.

FIG. 4C is a schematic top view of a micro light-emitting diode according to another embodiment of the disclosure.

FIG. 5 is a schematic cross-sectional view of a micro light-emitting diode according to another embodiment of the disclosure.

FIG. 6A is a schematic cross-sectional view of a micro light-emitting diode according to another embodiment of the disclosure.

FIG. 6B is a schematic top view of FIG. 6A.

FIGS. 7 to 12 are schematic cross-sectional views of various micro light-emitting diodes according to other embodiments of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

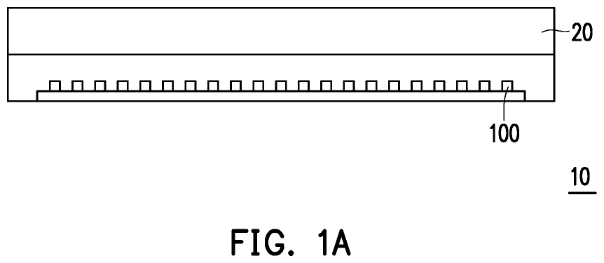

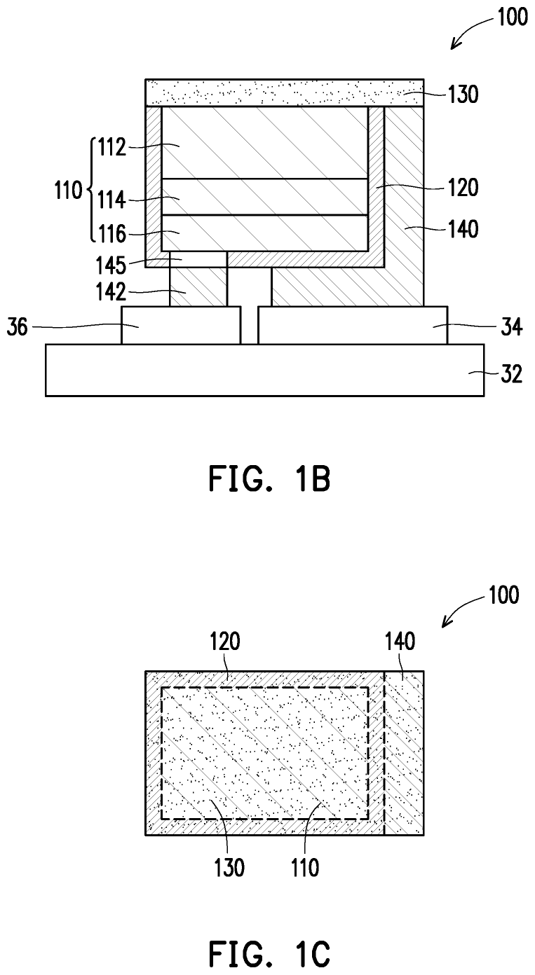

FIG. 1A is a schematic cross-sectional view of a display device according to an embodiment of the disclosure. Referring to FIG. 1A, a display device 10 of this embodiment includes a display panel 20 and multiple micro light-emitting diodes 100. The micro light-emitting diodes 100 are disposed on the display panel 20 and are electrically connected to the display panel 20. In this embodiment, the micro light-emitting diode 100 exhibits the following characteristics of a vertical light-emitting diode and a flip-chip light-emitting diode.

FIG. 1B is a schematic cross-sectional view of a micro light-emitting diode according to an embodiment of the disclosure. FIG. 1C is a schematic top view of FIG. 1B. Referring to FIGS. 1B and 1C, the micro light-emitting diode 100 of this embodiment is adapted for being disposed on and electrically connected to a circuit substrate 32. The micro light-emitting diode 100 includes an epitaxial structure 110, at least one first electrode 140, a second electrode 142, and an insulating layer 120.

The epitaxial structure 110 includes a first semiconductor layer 112, a light emitting layer 114, and a second semiconductor layer 116 stacked in sequence. In this embodiment, the first semiconductor layer 112 is, for example, a P-type semiconductor layer, the second semiconductor layer 116 is, for example, an N-type semiconductor layer, and the light emitting layer 114 is a multiple quantum well layer.

At least one first electrode 140 is electrically connected to the first semiconductor layer 112 and extends from a side of the first semiconductor layer 112 along at least one side surface of the epitaxial structure 110 to below the second semiconductor layer 116. In this embodiment, an example is given in which the number of the at least one first electrode 140 is one, but in other embodiments, more than one first electrodes 140 may be provided. The disclosure is not limited thereto.

In addition, in this embodiment, the first electrode 140 is L-shaped, a part of the first electrode 140 is located on a side surface of the epitaxial structure 110, and another part of the first electrode 140 is located below the epitaxial structure 110, but the form of the first electrode 140 is not limited thereto. The part of the first electrode 140 on the side surface of the epitaxial structure 110 and the part of the first electrode 140 below the epitaxial structure 110 may be integrally formed to increase the yield.

The second electrode 142 is located below the second semiconductor layer 116 and is electrically connected to the second semiconductor layer 116. In this embodiment, the micro light-emitting diode 100 further includes an ohmic contact layer 145 disposed between the second electrode 142 and the second semiconductor layer 116. The second electrode 142 is electrically connected to the second semiconductor layer 116 through the ohmic contact layer 145, so as to facilitate the electrical connection between the second electrode 142 and the second semiconductor layer 116. In embodiments not shown in the drawings, the ohmic contact layer 145 may be omitted. In this embodiment, an example is given in which the number of the second electrode 142 is one, but in other embodiments, more than second electrodes 142 may be provided.

In this embodiment, the first electrode 140 and the second electrode 142 are located on the same side of the epitaxial structure 110. Therefore, the first electrode 140 and the second electrode 142 may be connected to a first bonding pad 34 and a second bonding pad 36 on the circuit substrate 32 respectively.

In addition, in this embodiment, the projection area of the first electrode 140 on the circuit substrate 32 is greater than or equal to the projection area of the second electrode 142 on the circuit substrate 32. Such a design allows the first electrode 140 to have a larger area to bond with the first bonding pad 34 of the circuit substrate 32. With the larger bonding area, the bonding force may be evenly distributed to increase the bonding yield.

In addition, since the first electrode 140 is disposed on the side surface of the epitaxial structure 110, the first electrode 140 may be used as a reflective layer to reflect the light incident onto the side surface of the epitaxial structure 110 upward. Accordingly, the light output efficiency is facilitated.

The insulating layer 120 is disposed at least between the at least one first electrode 140 and the light emitting layer 114 and between the at least one first electrode 140 and the second semiconductor layer 116 of the epitaxial structure 110. In this embodiment, the insulating layer 120 is further disposed between the at least one first electrode 140 and the first semiconductor layer 112 of the epitaxial structure 110. That is, the insulating layer 120 separates the first electrode 140 and the entire epitaxial structure 110.

In this embodiment, the micro light-emitting diode 100 further includes a conductive layer 130, which is disposed on the first semiconductor layer 112 and is in ohmic contact with the first semiconductor layer 112. The first electrode 140 contacts and is electrically connected to the conductive layer 130. That is, in this embodiment, the first electrode 140 is electrically connected to the first semiconductor layer 112 through the conductive layer 130. In this embodiment, the conductive layer 130 is a transparent conductive layer 130, and the light generated by the epitaxial structure 110 passes through the conductive layer 130 and emits upward. The conductive layer 130 is capable of conducting electricity and transmitting light. The material of the conductive layer 130 includes, for example, ITO, AZO, or ZnO, but the material and form of the conductive layer 130 are not limited thereto.

In addition, as shown in FIG. 1B, the thickness of the conductive layer 130 is smaller than the thickness of the first electrode 140. Since the conductive layer 130 has a smaller thickness, the proportion of light absorbed may be reduced when the light passes through the conductive layer 130. Thus, the micro light-emitting diode 100 has a favorable light output amount. Meanwhile, through the contact and electrical connection between the conductive layer 130 the first electrode 140, the micro light-emitting diode 100 has a favorable efficiency, so as to prevent the light from the epitaxial structure from being shielded by the first electrode disposed on the epitaxial structure in the related art.

In this embodiment, the conductive layer 130 covers the epitaxial structure 110, the first electrode 140, and the insulating layer 120. Therefore, the projection area of the conductive layer 130 on the circuit substrate 32 entirely covers the projection areas of the epitaxial structure 110, the first electrode 140, and the insulating layer 120 on the circuit substrate 32. Accordingly, the current conducting efficiency is facilitated. It is to be noted that in other embodiments, the relative relationship between the conductive layer 130 and the epitaxial structure 110 and the insulating layer 120 is not limited thereto.

It is worth mentioning that the first electrode 140 of the micro light-emitting diode 100 of this embodiment extends from the conductive layer 130 along the side surface of the epitaxial structure 110 to below the second semiconductor layer 116, and the second electrode 142 is located below the second semiconductor layer 116. Therefore, different from the vertical micro light-emitting diode in the conventional art, the first electrode 140 and the second electrode 142 of the micro light-emitting diode 100 of this embodiment are located on the same side of the epitaxial structure 110. Each of the first electrode 140 and the second electrode 142 may thereby be directly bonded to the circuit substrate 32 individually without wire bonding or using co-electrodes. Consequently, the bonding yield is facilitated.

In addition, different from the flip-chip light-emitting diode in the related art, the micro light-emitting diode 100 of this embodiment has the design of the first electrode 140 extending from a side of the first semiconductor layer 112 along at least one side surface of the epitaxial structure 110 to below the second semiconductor layer 116. In this way, it is not required to manufacture a conductive hole or a mesa on the epitaxial structure 110, and the size of the epitaxial structure 110 may be reduced to less than 30 microns. Therefore, the epitaxial structure 110 has a smaller size.

It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

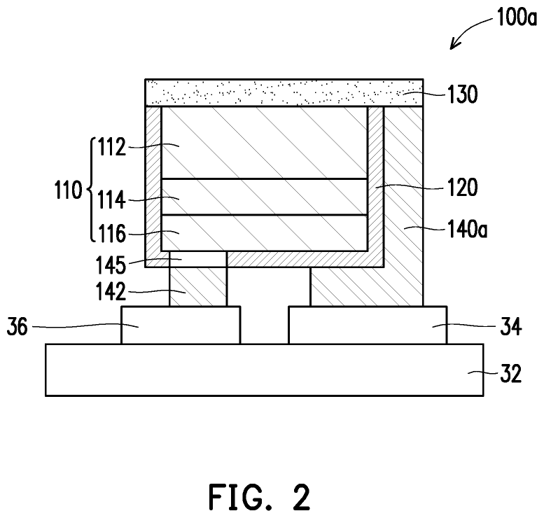

FIG. 2 is a schematic cross-sectional view of a micro light-emitting diode according to another embodiment of the disclosure. Referring to FIG. 2, the main difference between a micro light-emitting diode 100a of FIG. 2 and the micro light-emitting diode 100 of FIG. 1B is that: in FIG. 1B, the projection area of the first electrode 140 on the epitaxial structure 110 is larger than the projection area of the second electrode 142 on the epitaxial structure 110. That is, the size of the first electrode 140 below the epitaxial structure 110 is larger than the size of the second electrode 142 below the epitaxial structure 110. In this embodiment, the projection area of a first electrode 140a on the epitaxial structure 110 is equal to the projection area of the second electrode 142 on the epitaxial structure 110. That is, the size of the first electrode 140a below the epitaxial structure 110 is equal to the size of the second electrode 142 below the epitaxial structure 110. Since the thickness of the micro light-emitting diode 100 is less than or equal to 10 microns, through the balanced bonding area, the bonding yield may be facilitated, and damages to the micro light-emitting diode 100 may be avoided. It is to be noted that the size relationship between the first electrode 140a and the second electrode 142 is not limited thereto.

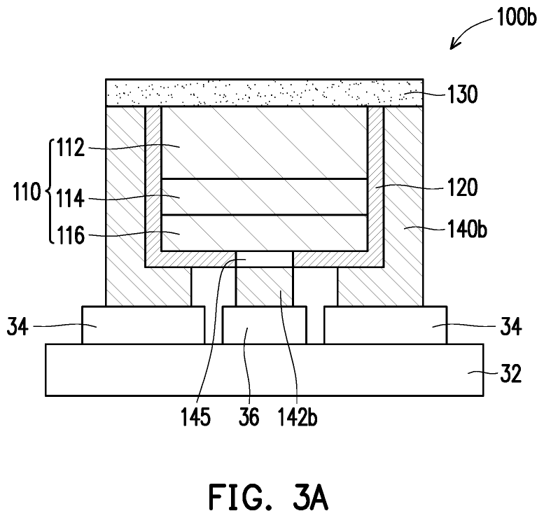

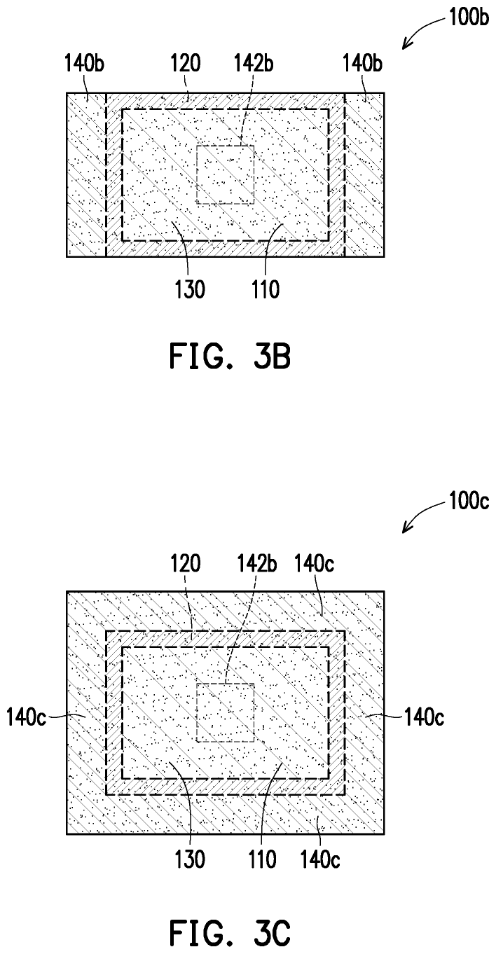

FIG. 3A is a schematic cross-sectional view of a micro light-emitting diode according to another embodiment of the disclosure. FIG. 3B is a schematic top view of FIG. 3A. Referring to FIGS. 3A and 3B, the main difference between a micro light-emitting diode 100b in FIG. 3A and the micro light-emitting diode 100 in FIG. 1B is that: in this embodiment, at least one first electrode 140b includes multiple first electrodes 140b, at least one side surface includes multiple side surfaces, and the multiple first electrodes 140b extend along the multiple side surfaces of the epitaxial structure 110 to below the second semiconductor layer 116. In this embodiment, the number of the multiple first electrodes 140b is two, and the two first electrodes 140b extend from two opposite side surfaces of the epitaxial structure 110 (the left side surface and the right side surface shown in FIG. 3A) to below the second semiconductor layer 116.

In this embodiment, by increasing the number of the multiple first electrodes 140b, the reflection area on the side surfaces of the epitaxial structure 110 increases. Consequently, the light output efficiency is further facilitated.

In addition, in this embodiment, since the number of the multiple first electrodes 140b increases, if one of the multiple first electrodes 140b breaks, the other first electrode 140b may remain operational. Consequently, the probability of failure of the micro light-emitting diode 100b is reduced.

Furthermore, the epitaxial structure 110 generally has fewer defects in the center during manufacturing. In this embodiment, since the first electrodes 140b are configured on the side surfaces of the epitaxial structure 110 and the number of the first electrodes 140b is plural, a second electrode 142b is re-arranged to a position corresponding to the center of the epitaxial structure 110. Such a design allows the second electrode 142b to be located at a part corresponding to the position of the epitaxial structure 110 with fewer defects. Therefore, the micro light-emitting diode 100b may have a higher light-emitting efficiency and a higher external quantum efficiency (EQE).

FIG. 3C is a schematic top view of a micro light-emitting diode according to another embodiment of the disclosure. Referring to FIG. 3C, the main difference between a micro light-emitting diode 100c of FIG. 3C and the micro light-emitting diode 100b of FIG. 3B is that: in this embodiment, the number of first electrodes 140c is four, the four first electrodes 140c extend from the four side surfaces of the epitaxial structure 110 to below the second semiconductor layer 116, and the four first electrodes 140c are integrally formed and connected to each other to cover the four sides of the epitaxial structure 110. In an embodiment that is not shown, the four first electrodes 140c may also separately cover the four sides of the epitaxial structure 110.

Such a design provides a more comprehensive reflecting effect of the light on the four side surfaces of the epitaxial layer, and allows the multiple first electrodes 140c of the micro light-emitting diode 100c to have a larger bonding area, so as to further increase the bonding margin between the multiple first electrodes 140c and the first bonding pad 34 of the circuit substrate 32. The micro light-emitting diode 100c can remain operational even if there is a slight misalignment between the micro light-emitting diode 100c and the circuit substrate 32.

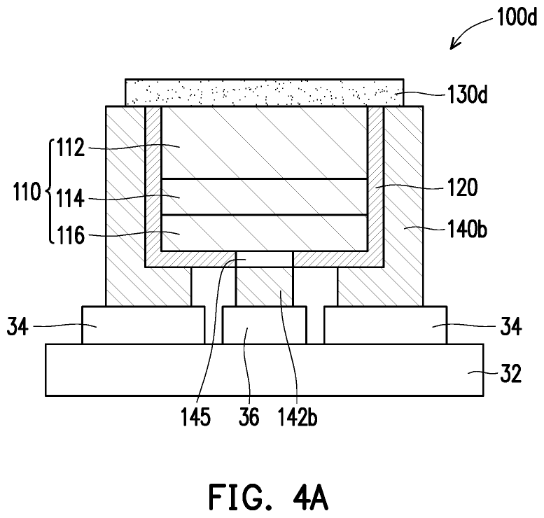

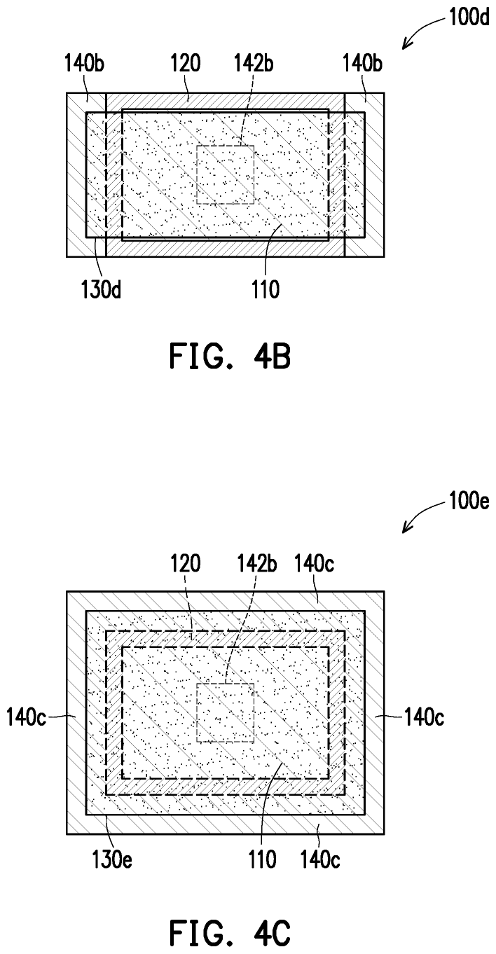

FIG. 4A is a schematic cross-sectional view of a micro light-emitting diode according to another embodiment of the disclosure. FIG. 4B is a schematic top view of FIG. 4A. Referring to FIGS. 4A and 4B, the main difference between a micro light-emitting diode 100d in FIG. 4A and the micro light-emitting diode 100b in FIG. 3A is that: in this embodiment, the edges of a conductive layer 130d are retracted, and parts of the first electrodes 140b are exposed. Therefore, the projection area of the conductive layer 130d on the circuit substrate 32 is smaller than the projection area of the epitaxial structure 110, the first electrodes 140b, and the insulating layer 120 on the circuit substrate 32.

FIG. 4C is a schematic top view of a micro light-emitting diode according to another embodiment of the disclosure. Referring to FIG. 4C, similarly, the main difference between a micro light-emitting diode 100e of FIG. 4C and the micro light-emitting diode 100c of FIG. 3C is that: in this embodiment, the edges of a conductive layer 130e are retracted, and parts of the first electrodes 140c are exposed. Therefore, the projection area of the conductive layer 130e on the circuit substrate 32 is smaller than the projection area of the epitaxial structure 110, the first electrodes 140c, and the insulating layer 120 on the circuit substrate 32.

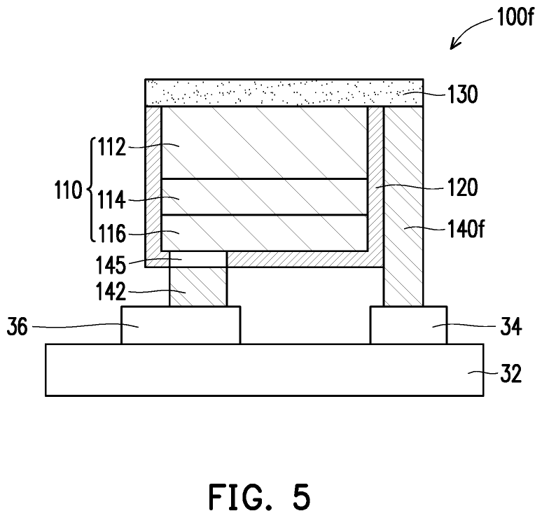

FIG. 5 is a schematic cross-sectional view of a micro light-emitting diode according to another embodiment of the disclosure. Referring to FIG. 5, the main difference between a micro light-emitting diode 100f of FIG. 5 and the micro light-emitting diode 100 of FIG. 1B is that: in FIG. 1B, the first electrode 140 is L-shaped, and the first electrode 140 extends from the side surface of the epitaxial structure 110 to directly below the epitaxial structure 110. In this embodiment, a first electrode 140f is I-shaped, and the first electrode 140f extends vertically downward from a side surface of the epitaxial structure 110, but does not extend to directly below the epitaxial structure 110. Therefore, the projection area of the first electrode 140f on the circuit substrate 32 does not overlap with the projection area of the epitaxial structure 110 on the circuit substrate 32, and the design of the I-shaped first electrode 140f may increase the manufacturing yield of the first electrode 140f.

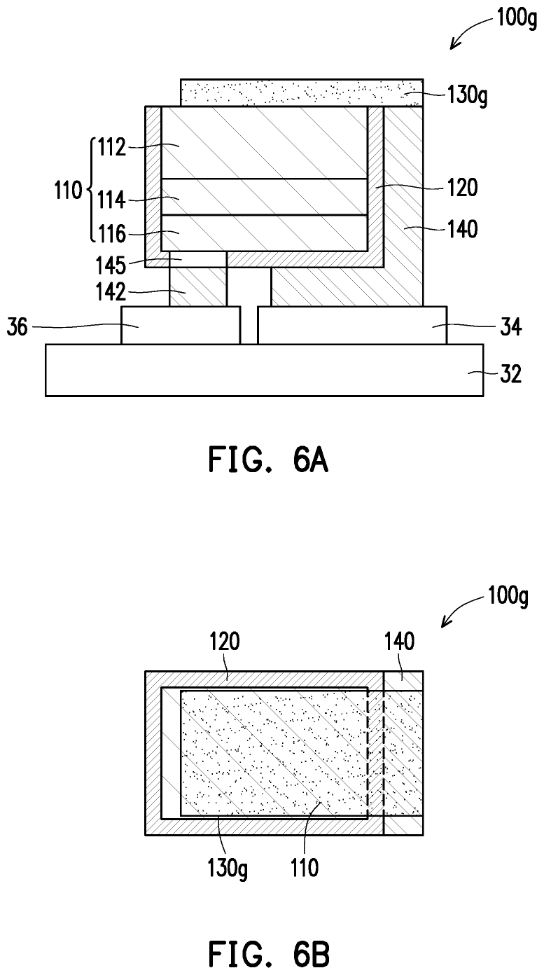

FIG. 6A is a schematic cross-sectional view of a micro light-emitting diode according to another embodiment of the disclosure. FIG. 6B is a schematic top view of FIG. 6A. Referring to FIGS. 6A and 6B, the main difference between a micro light-emitting diode 100g in FIG. 6A and the micro light-emitting diode 100b in FIG. 1B is that: in this embodiment, a conductive layer 130g does not entirely cover the epitaxial structure 110 and the insulating layer 120.

In general, the epitaxial structure 110 has fewer defects in the center during manufacturing. As shown in FIG. 6B, the conductive layer 130g is disposed at a position corresponding to the center of the epitaxial structure 110 and extends toward the first electrode 140. In the top view of FIG. 6B, the upper, left, and lower edges of the conductive layer 130g are retracted, so as to reduce the conductive layer 130g disposed on the upper, left, and lower sides of the epitaxial structure 110 and the insulating layer 120 in the top view of FIG. 6B. Such a configuration reduces the probability of the current flowing through the edges of the epitaxial structure 110 on the upper, left, and lower sides. Thus, the current concentrates in the center of the epitaxial structure 110. In addition, such a configuration reduces the shielding of the conductive layer 130g, and the micro light-emitting diode 100g therefore has a higher light-emitting efficiency.

In this embodiment, the projection area of the conductive layer 130g on the epitaxial structure 110 covers 80% or more of the area of the epitaxial structure 110 and therefore allows a large current to pass through, but the coverage of the projection area of the conductive layer 130g on the epitaxial structure 110 is less than 100% of the area of the epitaxial structure 110 so as to reduce the probability of the current flowing through the edges of the epitaxial structure 110. In addition, in this embodiment, the conductive layer 130g only covers a part of the epitaxial structure 110 and the first electrode 140. Therefore, the ratio of the projection area of the conductive layer 130g on the circuit substrate 32 to the projection area of the epitaxial structure 110 to the circuit substrate 32 may be between 80% and 110%, but is not limited thereto.

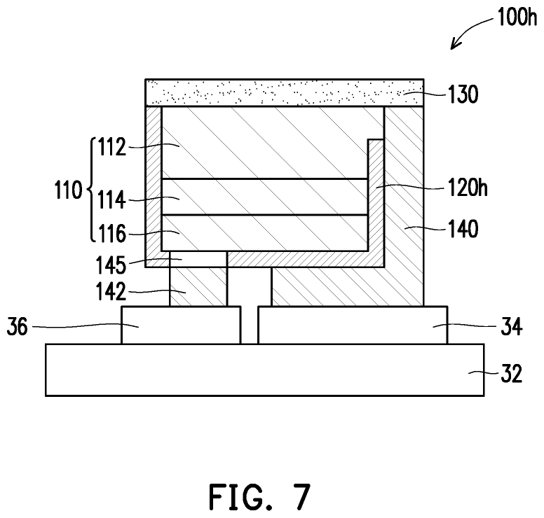

FIGS. 7 to 12 are schematic cross-sectional views of various micro light-emitting diodes according to other embodiments of the disclosure. Referring to FIG. 7, the main difference between a micro light-emitting diode 100h of FIG. 7 and the micro light-emitting diode 100 of FIG. 1B is that: in this embodiment, an insulating layer 120h does not separate the first electrode 140 and the first semiconductor layer 112, and the first electrode 140 directly contacts the first semiconductor layer 112. Specifically, the first electrode 140 directly contacts a sidewall of the first semiconductor layer 112. When the micro light-emitting diode 100h emits blue, green or yellow light, the material of the first semiconductor layer 112 is a Group III-V material, and the first semiconductor layer 112 may be in direct ohmic contact with the first electrode 140.

Therefore, in this embodiment, the first electrode 140 may be in direct ohmic contact with the first semiconductor layer 112 in addition to the ohmic contact through the conductive layer 130. Consequently, the circuit path is reduced.

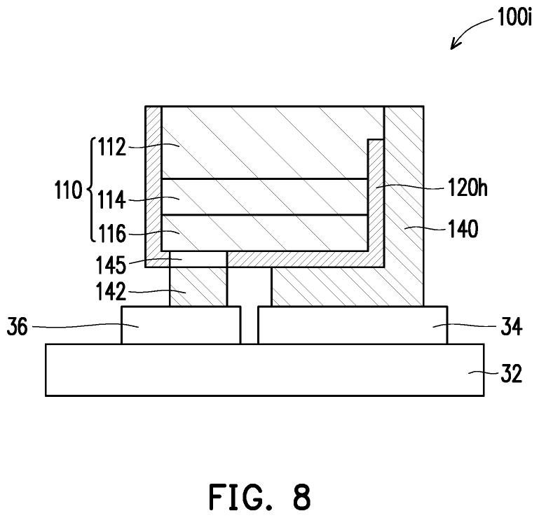

Referring to FIG. 8, the main difference between a micro light-emitting diode 100i of FIG. 8 and the micro light-emitting diode 100h of FIG. 7 is that: in this embodiment, the micro light-emitting diode 100i does not have the conductive layer 130 of FIG. 7. Since the first semiconductor layer 112 may be directly in ohmic contact with the first electrode 140 without relying on the conductive layer 130 when the material of the first semiconductor layer 112 is a Group III-V material, in this embodiment, the conductive layer 130 (in FIG. 7) may be omitted.

It is to be noted that compared with the conductive layer 130 (in FIG. 7), the epitaxial structure 110 has a higher yield and favorable quality, so the bonding of the hetero-junction with the first electrode 140 is favorable, and, as a consequence, a favorable electrical connecting quality is rendered. In this embodiment, the conductive layer 130 (in FIG. 7) is omitted, and the first semiconductor layer 112 is directly in ohmic contact with the first electrode 140. With such configuration, the overall yield may be increased.

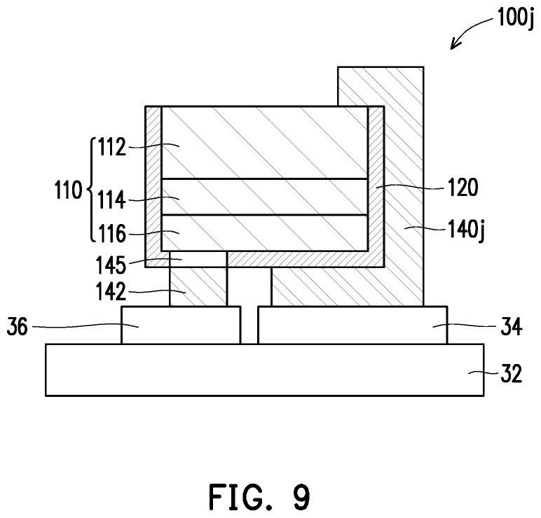

Referring to FIG. 9, the main difference between a micro light-emitting diode 100j of FIG. 9 and the micro light-emitting diode 100i of FIG. 8 is that: in this embodiment, the insulating layer 120 separates the first semiconductor layer 112 and a first electrode 140j, and the first electrode 140j extends to directly above the first semiconductor layer 112, and is in direct ohmic contact with the first semiconductor layer 112 above the first semiconductor layer 112.

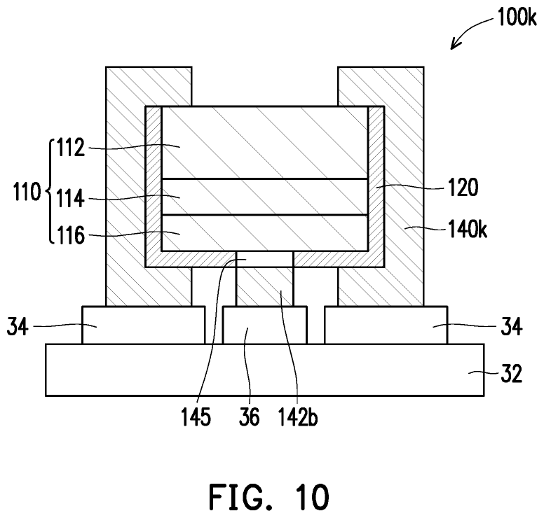

Referring to FIG. 10, the main difference between a micro light-emitting diode 100k of FIG. 10 and the micro light-emitting diode 100j of FIG. 9 is that: in this embodiment, multiple first electrodes 140k are provided. The multiple first electrodes 140k extend from the upper surface of the epitaxial structure 110 along the side surfaces to below the second semiconductor layer 116.

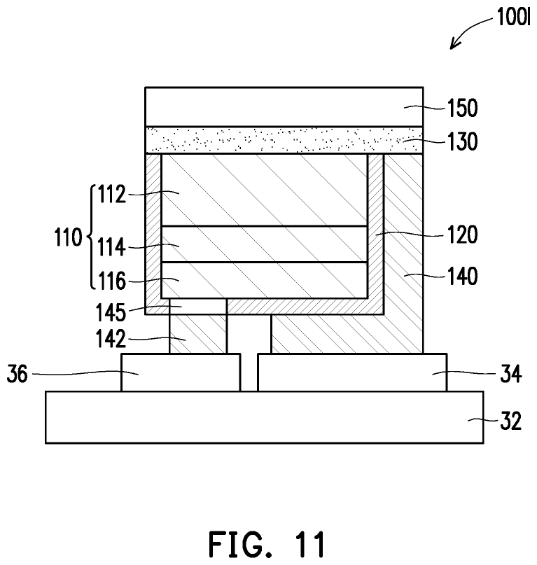

Referring to FIG. 11, the main difference between a micro light-emitting diode 100l of FIG. 11 and the micro light-emitting diode 100 of FIG. 1B is that: in this embodiment, the micro light-emitting diode 100l further includes a first light guide layer 150, disposed on the conductive layer 130, and the conductive layer 130 is located between the first light guide layer 150 and the first semiconductor layer 112. The refractive index of the conductive layer 130 is greater than the refractive index of the first light guide layer 150. Accordingly, the light output efficiency is increased. The first light guide layer 150 includes, for example, SiN, but the type of the first light guide layer 150 is not limited thereto.

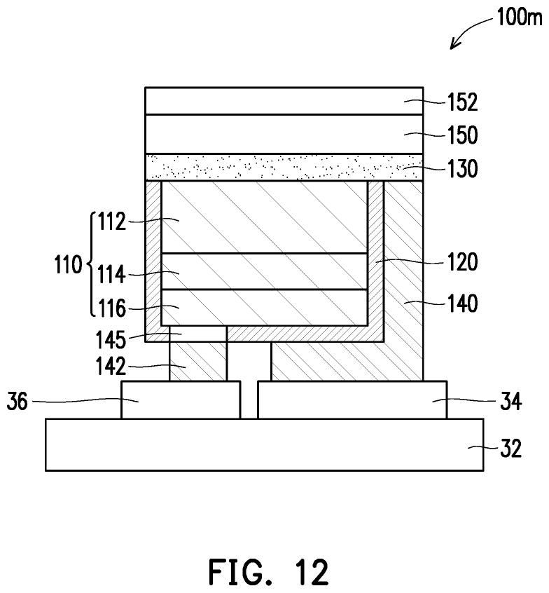

Referring to FIG. 12, the main difference between a micro light-emitting diode 100m of FIG. 12 and the micro light-emitting diode 100l of FIG. 11 is that: in this embodiment, the micro light-emitting diode 100m further includes a second light guide layer 152, disposed on the first light guide layer 150, and the first light guide layer 150 is located between the second light guide layer 152 and the conductive layer 130. The refractive index of the first light guide layer 150 is greater than the refractive index of the second light guide layer 152. Accordingly, the light output efficiency is further increased. The second light guide layer 152 includes, for example, SiO₂, but the type of the second light guide layer 152 is not limited thereto.

In summary, the first electrode of the micro light-emitting diode according to the embodiments of the disclosure extends from a side of the first semiconductor layer along at least one side surface of the epitaxial structure to below the second semiconductor layer, and the second electrode is located below the second semiconductor layer. Therefore, different from a vertical light-emitting diode, the first electrode and the second electrode of the micro light-emitting diode according to the embodiments of the disclosure are located on the same side of the epitaxial structure. The first electrode and the second electrode can be directly bonded to the circuit substrate without wire bonding. Thus, the bonding yield is increased. In addition, different from a flip-chip light-emitting diode, the micro light-emitting diode according to the embodiments of the disclosure has the design of the first electrode extending from a side of the first semiconductor layer along at least one side surface of the epitaxial structure to below the second semiconductor layer. In this way, it is not required to manufacture a conductive hole or a mesa on the epitaxial structure. As a result, the micro light-emitting diode has a smaller size. That is, the micro light-emitting diode according to the embodiments of the disclosure exhibits the characteristics of the vertical light-emitting diode and the flip-chip light-emitting diode.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A micro light-emitting diode, adapted for being disposed on and electrically connected to a circuit substrate, wherein the micro light-emitting diode comprises:
an epitaxial structure, comprising a first semiconductor layer, a light emitting layer, and a second semiconductor layer stacked in sequence;
at least one first electrode, electrically connected to the first semiconductor layer and extending from a side of the first semiconductor layer along at least one side surface of the epitaxial structure to between the second semiconductor layer and the circuit substrate;
a second electrode, located below the second semiconductor layer and electrically connected to the second semiconductor layer; and
an insulating layer, disposed at least between the at least one first electrode and the light emitting layer of the epitaxial structure and between the at least one first electrode and the second semiconductor layer.

2. The micro light-emitting diode according to claim 1 further comprising:
a conductive layer, disposed on the first semiconductor layer and contacting the first semiconductor layer, wherein the at least one first electrode contacts and is electrically connected to the conductive layer.

3. The micro light-emitting diode according to claim 2, wherein a projection area of the conductive layer on the circuit substrate entirely covers projection areas of the epitaxial structure, the at least one first electrode, and the insulating layer on the circuit substrate.

4. The micro light-emitting diode according to claim 2, wherein a projection area of the conductive layer on the circuit substrate is smaller than a projection area of the epitaxial structure, the at least one first electrode and the insulating layer on the circuit substrate.

5. The micro light-emitting diode according to claim 2, wherein a projection area of the conductive layer on the epitaxial structure covers 80% or more of an area of the epitaxial structure.

6. The micro light-emitting diode according to claim 2, wherein a ratio of a projection area of the conductive layer on the circuit substrate to a projection area of the epitaxial structure on the circuit substrate is between 80% and 110%.

7. The micro light-emitting diode according to claim 2, wherein a thickness of the conductive layer is smaller than a thickness of each of the at least one first electrode.

8. The micro light-emitting diode according to claim 2 further comprising:
a first light guide layer, disposed on the conductive layer, wherein the conductive layer is located between the first light guide layer and the first semiconductor layer, and a refractive index of the conductive layer is greater than a refractive index of the first light guide layer.

9. The micro light-emitting diode according to claim 8 further comprising:
a second light guide layer, disposed on the first light guide layer, wherein the first light guide layer is located between the second light guide layer and the conductive layer, and a refractive index of the first light guide layer is greater than a refractive index of the second light guide layer.

10. The micro light-emitting diode according to claim 1, wherein a projection area of each of the at least one first electrode on the circuit substrate is greater than or equal to a projection area of the second electrode on the circuit substrate.

11. The micro light-emitting diode according to claim 1, wherein a projection area of the at least one first electrode on the epitaxial structure is equal to a projection area of the second electrode on the epitaxial structure.

12. The micro light-emitting diode according to claim 1, wherein the at least one first electrode comprises a plurality of first electrodes, the at least one side surface comprises a plurality of side surfaces, and the plurality of the first electrodes extend along the plurality of the side surfaces of the epitaxial structure to below the second semiconductor layer.

13. The micro light-emitting diode according to claim 1, wherein a projection area of the at least one first electrode on the circuit substrate does not overlap with a projection area of the epitaxial structure on the circuit substrate.

14. The micro light-emitting diode according to claim 1, wherein the at least one first electrode directly contacts the first semiconductor layer.

15. The micro light-emitting diode according to claim 14, wherein the at least one first electrode extends onto the first semiconductor layer.

16. A micro light-emitting diode display device, comprising:
a display panel; and
a plurality of micro light-emitting diodes according to claim 1 disposed on the display panel and electrically connected to the display panel.
